(19) United States
(12) Patent Application Publication
(10) Pub. No.: US 2011/0035161 A1
(43) Pub. Date: Feb. 10, 2011

(54) ANALOG SIGNAL MEASUREMENT SYSTEM AND GAMMA RAY DETECTOR WITH TARGETED AUTOMATED GAMMA SPECTROSCOPY

(76) Inventors: Robert Cassin McFadden, Adjala Township (CA); Christopher James McInnis Clarke, Ottawa (CA)

Correspondence Address: Muncy, Geissler, Olds & Lowe, PLLC, 4000 Legato Road, Suite 310, FAIRFAX, VA, 22033, US

(21) Appl. No.: 12/988,017

(22) PCT Filed: Apr. 15, 2009
(86) PCT No.: PCT/CA2009/000492

§ 371 Date: Oct. 15, 2010

Related U.S. Application Data
(60) Provisional application No. 61/045,089, filed on Apr. 15, 2008.

(51) Int. Cl. G01N 23/00; G06F 15/00; G06F 19/00; G01R 23/10

(52) U.S. Cl. 702/28; 702/189; 702/78

(57) ABSTRACT

An analog signal measurement system and a gamma ray detector with targeted automated gamma spectroscopy for gamma radiation surveillance system are disclosed. The analog signal measurement system has dynamically programmable lower and upper level discriminators for measuring an analog signal thereagainst, and logic devices for receiving input from the discriminators to generate digital signals. The gamma ray detector comprises a gamma ray detector for converting a gamma ray photon into an analog pulse, and a single channel analyzer or the analog signal measurement system. The gamma ray detector further includes dynamically programmable lower and upper level discriminators for converting the analog pulse generated from the gamma ray detector into a digital signal, a resettable programmatically controlled counter for counting the digital signal and a computing device that controls the lower and upper level discriminators for defining a gamma ray energy window and measures gamma count rate for that energy window.

### CLAIM OF PRIORITY

This Application claims priority from U.S. Provisional Patent Application Ser. No. 61/045,089, filed on Apr. 15, 2008, which application is incorporated by reference herein.

### FIELD OF INVENTION

The present invention relates to analog measurement systems and their application to gamma ray detectors for a surveillance system, and in particular relates to a gamma ray detector with targeted automated gamma spectroscopy for a gamma radiation surveillance system.

### BACKGROUND OF THE INVENTION

Since the terrorist events of Sep. 11, 2001, the likelihood of future terrorist attacks is acknowledged to be higher than in the past. As a result, the public has greater expectations for security, prevention, interdiction and incident site management. Radiological agents have a particularly high potential for psycho-social impacts on political and economic systems. The malicious dispersal and/or the clandestine placement of radioactive material could be used to attack civil, governmental and economic targets. Thus adequate prevention and response systems are needed.

In fact, significant radiological sources could be acquired by terrorists through purchase, theft or low level military operations and moved, possibly undetected, to urban population areas or to targets of high symbolic value. There is a continuing need for increased capability to collect radiological surveillance information, which would provide more consistent, reliable and prompt data for incident management by homeland security authorities.

It is expected that terrorists will shift their focus of attack to new methods, agents and new targets as historical targets become hardened. Further, well resourced and established terrorist organizations are expected to seek to extend the scope of their attack options to include less conventional agents and methods including radiological attack. Gamma ray emitting radiological materials will be effective agents for radiological attack because of their properties.

The beneficial medical and industrial applications of radioactive materials have led to the location of significant inventories in or near high value terrorist targets. Weakly secured sources of highly penetrating radiation with strengths ranging up to 10,000 Curies are vulnerable to theft and either announced or unannounced dispersal and/or placement.

Additionally, there are increasing numbers of ambulatory medical patients carrying benign body burdens of radiopharmaceuticals which are important to distinguish from illicit and lost (orphaned) radioactive sources which may be of potential public health concern.

Conventional security surveillance systems operating in critical infrastructure sites which admit the public generally lack suitable radiological threat agent detection capabilities. A major determining factor for this shortfall is the previous unavailability of an illicit radiological threat agent sensor which is capable of cost-effective deployment, particularly in harsh environments.

A key aspect of any surveillance technology cost effectiveness in public access venues is the capability of the surveillance system to maintain acceptably low false positive rates (Type I error) by ignoring normal or benign components of routine activities in a publicly accessed environment. Simultaneously that same surveillance system must ensure acceptably low false negative rates (Type II error) for actual threat agents. Conventional security systems have not adopted the previously available radiological threat agent detectors because of the high false positive and high false negative rates inherent in their designs despite the increasing recognition by security authorities of the likelihood of a radiological attack,

Public venues require a constant and short time scale for security surveillance in order to maintain the rapid movement of the public through the venue. Typically only one second or less is available for screening each member of the public. Additionally public venues usually present demanding environments for surveillance technologies such as extremes of heat, cold, temperature change rates, vibration and acceleration and water/moisture. Previous radiological security technologies have not adequately addressed public venue environments and requirements for rapid and reliable operation.

Additionally, public venues present the additional problems of widely variable radiation backgrounds due to construction materials, meteorological variations, and the unpredictable presence of licit radioactive materials such as radiopharmaceuticals and certain industrial radioactive sources. There has previously been no cost effective and ruggedized radiological sensor available to address the specific problems of radiological security in public venues.

Various radiological surveillance systems have been proposed or deployed. Generally these systems consist of either high cost static portal radiation sensors or operator carried hand held radiation detectors. Some systems alarm or otherwise report radiation data in order to make possible detection of illicit radiological materials presence and thereby make response possible. However, such stand alone systems result in an undesirable gap in time between the first opportunity to identify illicit radiation and the availability of that information to security operations decision makers.

One alternate approach to a radiation surveillance system was disclosed in U.S. Patent Application Publication No. 2005/0104773, and Canada Patent Application No. 2,471,195. The system disclosed in these applications integrates existing technological solutions to develop a capacity to fill the aforementioned radiological surveillance gap. This system is usable in critical infrastructure protection, routine police patrol work and to provide radiological situational awareness to security operations centers. It automatically transfers radiation data in real time by wireless or wired communication systems for analysis by sensitive signal detection technology. Security decision makers, for the first time, have access to prompt, well-defined and reliable radiation data and actionable situational information for attack prevention and interdiction, incident response and management, safety, and forensics.

The system detects the transport and storage of illicit radiologicals before an attack achieves target proximity, thus meeting security needs for early detection and warning. Early detection makes interdiction possible. The system provides greatly enhanced capabilities for police and command and control to assess radiation data in real time for public safety and incident management.

The mobile and static system brings various radiation sensors and radio communications together with event-detection algorithms to provide on-site rapid detection and identification of radiologicals. The system provides forensic capabilities for radiologicals by promptly deploying real-time evidence collection sensor technologies capable of contamination mapping.

Thus, there is a long felt need for a surveilance system that addresses at least one or more of the above identified needs for enhanced radiological security and it is desirable to implement a radiological threat agent radiation sensor system which is suited for radiological threat agent surveillance meeting the constraints imposed by continuous and routine operation in public venues.

There is a need for a system that provides short time scale detection of anomalous gamma ray radiation levels and also short time scale categorization of both benign or normal public venue radiation sources as well as illicit radiological threat agents. There is also a need for a system that is readiliy capable of integration into conventional security systems and operations.

### SUMMARY OF THE INVENTION

The present invention relates to analog measurement systems and their application to gamma ray detectors for a surveillance system. Accordingly, an object of the present invention is to provide gamma ray detectors with targeted automated gamma spectroscopy for a gamma radiation surveillance system.

Another object of the present invention is to provide an analogue measurement system which can be employed to improve the capabilities of a gamma ray detector. This invention can be readily incorporated into a mobile and/or static radiation surveillance system to provide enhanced functionalities for the mobile and static system through the provision of capabilities for automated, ruggedized, and cost effective radiological species identification. Yet another object of the present invention is to provide an analogue measurement system which can dynamically sample an analogue signal using a plurality of discriminators under programmatic control.

According to one aspect of the invention, it provides a gamma ray detector with targeted automated gamma spectroscopy, that includes a scintillator that receives a gamma photon and converts the gamma photon to a light photon pulse, a photomultiplier tube that is in optical communication with the scintillator, the photomultiplier tube converts the light photon pulse from the scintillator to a charge pulse and amplifies at a programmable gain, a thermostat for measuring temperature of the photomultiplier tube, a single channel analyzer that is in communication with the photomultiplier tube, the single channel analyzer having a programmable upper level discriminator and a programmable lower level discriminator that defines a selectable gamma ray energy window, the single channel analyzer receives the charge pulse from the photomultiplier tube and generates a digital signal pulse upon determining that the charge pulse is within the selectable energy window by discriminating the charge pulse against the upper level discriminator and lower level discriminator, a resettable counter that is in communication with the single channel analyzer and receives and counts the standardized digital signal pulse from the single channel analyzer, and a computing device having a communication interface for communicating with a server, the computing device controls the programmable gain of the photomultiplier tube according to the temperature of the photomultiplier tube retrieved from the thermostat and other factors such as calibration considerations, programs the upper level discriminator and lower level discriminator accordingly to a predetermined window, and resets and retrieves a value from the resettable counter for calculating a gamma count rate.

### BRIEF DESCRIPTION OF THE DRAWINGS

The present invention will now be described in more detail with reference to the accompanying drawings, in which:

FIG. 1 is a functional block diagram of a gamma ray detector of the present invention;

FIG. 2 is a functional block diagram of a photomultiplier base with single channel analyzer of the gamma ray detector of FIG. 1;

FIG. 3 is a functional block diagram of a targeted automated gamma spectropy control module of the gamma ray detector of FIG. 1;

FIG. 4 is a functional block diagram of a main program of the gamma ray detector of FIG. 1;

FIG. 5 is a logic flow diagram of the main program of FIG. 4;

FIG. 6 is a functional block diagram of a high voltage control program of the gamma ray detector of FIG. 1;

FIG. 7 is a logic flow diagram of the high voltage control program of FIG. 6;

FIG. 8 is a sample user interface output of the gamma ray detector for illicit radiological;

FIG. 9 is another sample user interface output of the gamma ray detector for medical patient; and

FIG. 10 is yet another sample user interface output of the gamma ray detector for medical patient.

### DETAILED DESCRIPTION

System Components

A Gamma Ray Detector with Targeted Automated Gamma Spectroscopy (or detector system) 1 of the present invention incorporates (1) gamma ray radiation sensor technologies (scintillation or other) with (2) radiation detector analogue pulse height analysis electronics and detector serial number read out under computer program control, (3) microprocessor external device control input and output systems, (4) external device computer program control programs, (5) gamma ray detection and analysis computer programs, and (6) data storage and output computer programs for the retention and output of radiation data into a system suitable for radiation surveillance.

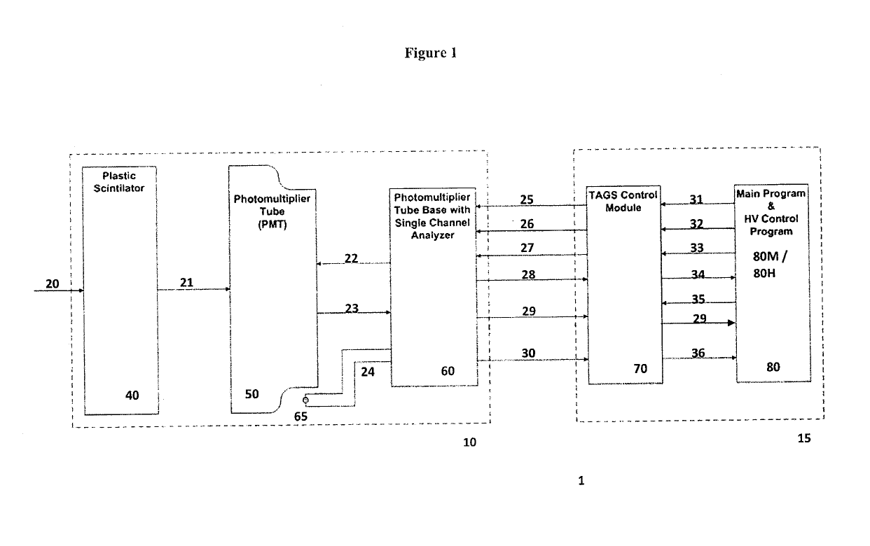

Reference is made to FIG. 1, the detector system 1 is comprised of the sensor portion 10 and detection unit 15. The sensor portion 10 includes, but not limited to, a plastic scintillator 40, photomultiplier tube 50, and photomultiplier tube base with single channel analyzer 60. The detector unit 15 includes targeted automated gamma spectroscopy (or TAGS) control module 70 and microprocessor or computing device 80, having main program 80M and high voltage control program 80H running therein.

The plastic scintillator 40 receives Gamma (γ) Photons 20 and converts the Gamma Ray (γ) Photons 20, emitted by an ionizing radiation source, into Light Photons 21. The intensity level of the Light Photon pulses 21 converted by the plastic scintillator 40 correspond proportionally (either in a linear or non-linear relationship) to the energy of the incident Gamma Ray Photons 20 received at the plastic scintillator 40.

The detector material must be sensitive to radiation and may be comprised of a plastic scintillator 40 or other radiation detection material. The detector and its sensitive material should possess characteristics suitable for various radiation surveillance applications, such as accommodating various operating environments. Scintillators and other radiation sensitive materials with their associated photomultipliers and their associated electronics produce electronic signals in response to exposure to radiation. These electronic signals contain information specifying the quantity of energy deposited by the radiation in the detector.

The Photomultiplier Tube (PMT) 50 is in optical communication with the plastic scintillator 40, and receives light photons (or light photon pulses) 21 from the plastic scintillator 40 via an optical link. The PMT 50 produces charge pulses 23 in response to exposure to light photon pulses 21. These charge pulses 23 are proportional to the amplitude of the light photon pulses 21 received by the PMT 50.

The High Voltage (HV) Control value 22 received by the PMT 50 controls the gain of the PMT 50 and, thus, controls the proportionality correlation between gamma energy received at the plastic scintillator 40 and the charge pulses 23 created by the PMT 50.

The PMT 50 also includes a thermistor 65 that provides the internal temperature of the PMT 50 to other external component(s). This temperature signal 24 is used to select a temperature-specific HV Control Value 22 and/or parameters, since the required high voltage at the PMT 50 is decided in part based on the operating temperature of PMT 50.

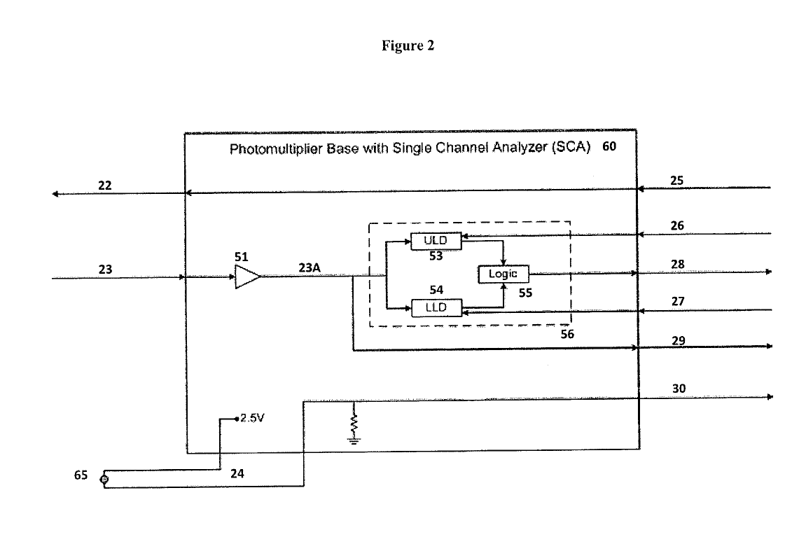

The Photomultiplier Tube Base with Single Channel Analyzer (SCA) 60 converts the charge pulses 23 into Output 28 from Single Channel Analyzer (SCA) 56 as shown in FIG. 2.

The Photomultiplier Base with SCA 60 amplifies the received charge pulse 23 by an amplifier 51, and measures the amplitude of the amplifier's Analog Pulse 23A (which is proportional to the gamma ray energy) and generates a standardized digital signal pulse or binary logic signal pulse (for example, TTL pulse) for input into a counting device. The SCA 56 permits discrimination against (i.e., rejection of) pulses below a certain lower amplitude threshold set by Low Level Discriminator (or LLD) 54 or above an upper threshold set by Upper Level Discriminator (or ULD) 53, allowing the measurement of only those events occurring in a selectable gamma ray energy window.

For example, the Charge Pulse 23 is amplified by the amplifier 51 into the Analog Pulse (a.k.a. Amplified Voltage Pulse) 23A. The Analog Pulse then feeds into the Single Channel Analyzer (SCA) 56 in the PMT Base with SCA 50. If the analog pulse's amplitude is higher than the LLD 54 and lower than the ULD 53, then a TTL Pulse is generated by a logic device 55 (for example, a Boolean logic device) as the SCA Output 28.

The LLD 54 and ULD 53 thresholds are modified dynamically via links 27 and 26, respectively by the TAGS Control Module 70 on the millisecond timescale to support the targeted automated gamma spectroscopy process.

The Temperature Output 30 is provided to the HV Control Program to select a temperature-specific HV Control Value via a link 25, as the operating HV of the PMT is slightly dependent on temperature.

The amplified Analog Pulse, amplified by the amplifier 51 is provided to the HV Control Program via a link 29.

Referencing back to FIG. 1, the detection unit 15 provides radiation sensor management by supporting requirements for power and bi-directional communication of commands and data. The Detection Unit 15 has an on-board processing device which associates radiation and other sensor output data with positioning and time stamp data and stores the resulting data sets in local memory or remotely in data storage on a server computer. Data may be transmitted on a time scale commensurate with a radiation measurement integration time or stored and batch transmitted on user defined or alarm determined schedules. Data is stored locally if telecommunications are lost and subsequently transmitted upon restoration of communications.

The Detection Unit is comprised of the TAGS Control Module 70, the main program 80M and the HV Control Program 80H. The Detection Unit may further include a Global Positioning System, telecommunications capabilities, power supplies appropriate to the operating conditions, etc.

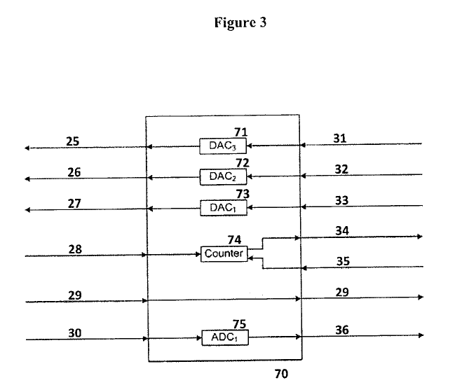

The TAGS Control Module 70 is implemented at the hardware level and its functionality is shown in the FIG. 3. The TAGS Control module 70 counts the number of SCA Output 28 (for example, TTL Pulses) received from the PMT Base with Single Channel Analyzer 60. A counter 74 provides output 34 to the Main Program 80M and takes input 35 from the Main Program 80M for resetting the counter 74. The Main Program 80M resets the counter 74 when required.

The TAGS Control Module 70 also does analog to digital conversion (ADC) 75 for converting temperature analog signal via link 30 to digital signal via link 36 thereof, and digital to analog conversions (DAC) 71, 72 and 73, DAC 71 converts HV Control signal 31 from HV Control Program 80H to analog HV Control signal 25, DAC 72 converts digital ULD threshold setting signal 32 from the Main Program 80M to analog ULD threshold setting 26, and DAC 73 converts digital LLD threshold setting signal 33 from the Main Program 80M to analog LLD threshold setting 27. The amplified Analog Pulse received via link 29 is passed to the Main Program 80M via link 29.

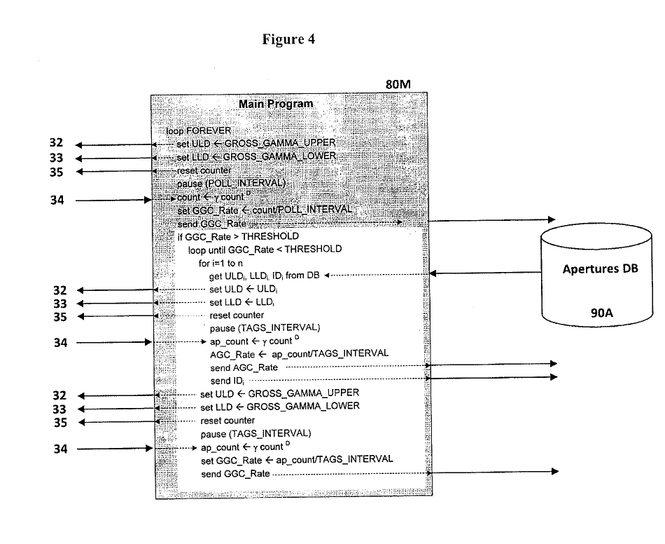

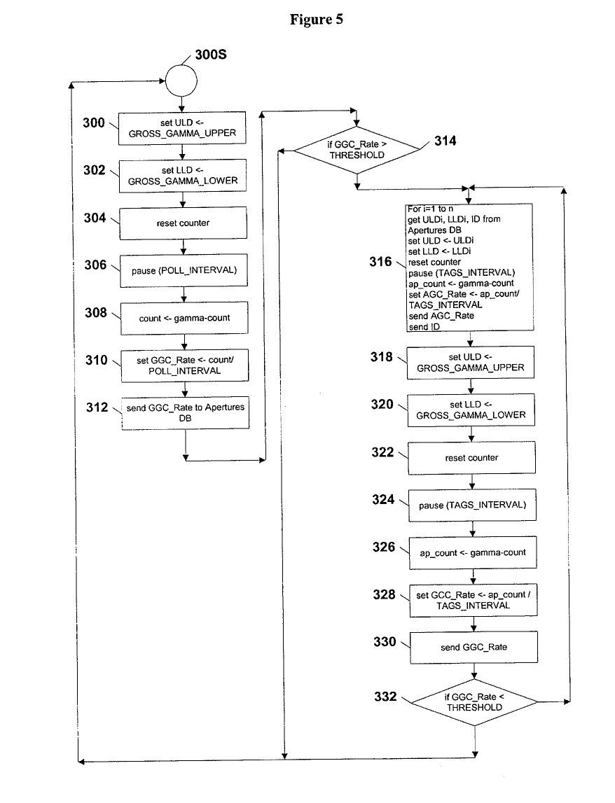

The Main Program 80M is preferably implemented in software that runs on the Detection Unit 15 and the pseudo code is provided in FIGS. 4 and 5.

The Main Program 80M, completes various initializations, starting from step 300S to loop forever for retrieving the gamma count (γCount or gamma-count) every POLL_INTERVAL and determining the Gross Gamma Count Rate (GGC_Rate), until a GGC_Rate exceeds the THRESHOLD, where POLL_INTERVAL is a polling interval when the Main Program 80M is not in targeted automated gamma spectroscopy (TAGS) mode, and THRESHOLD is a predetermined or variable value indicating a threshold for gamma counts, and above which the Main Program 80M should be in TAGS mode. In particular, At steps 300 and 302, the Main Program 80M causes ULD 53 to be set to a GROSS_GAMMA_UPPER threshold and LLD 54 to be set to GROSS_GAMMA_LOWER threshold, respectively. At step 304, the Main Program 80M resets the counter 74 and pauses for POLL-INTERVAL (a predetermined time interval) at step 306. The Main Program 80M, then, retrieves the count (γCount or gamma-count) from the counter 74 at step 308 and calculates gross gamma count rate (or GCC_Rate) by dividing the count value just retrieved from the counter 74 by the polling interval time, POLL_INTERVAL at step 310. The calculated GCC_Rate at step 310 is, then, sent to an Apertures Database 90A or a server (not shown, in communication therewith).

The calculated GCC_Rate at step 310 is compared with THRESHOLD (a programmable or predetermined value) at step 314. If GCC_Rate is equal to or below the THRESHOLD, the Main Program 80M returns to 300S to repeat the steps of 300 to 312. If the GCC_Rate is greater than Threshold, the Main Program 80M enters in TAGS mode or begins its targeted automated gamma spectroscopy (TAGS) functionality defined between steps 316 to 330.

During the TAGS functionality, at step 316, the Main Program 80M iterates through predetermined sets of apertures (i.e. 1 to n sets), which is defined by LLD and ULD threshold values stored in the Apertures Database 90A, each of which is retrievable by the Main Program 80M based on ID. Each aperture is used for the TAGS_INTERVAL duration. The TAGS_INTERVAL is the polling interval for each aperture when the Main Program 80M is in TAGS mode, and is typically in order of 100 s of milliseconds. For each aperture, the ULD and LLD thresholds are passed to ULD 53 and LLD 54 in the PMT Base with SCA 60 and, after the TAGS_INTERVAL, the Main Program 80M retrieves the gamma count (γCount or gamma-count) from the counter 74 for that specific aperture. The gamma count is then divided by the TAGS_INTERVAL to obtain the Aperture Gamma Count Rate (AGC_Rate) for the aperature. The AGC_Rates, as well as the respective identifier for the aperture, are sent to the Apertures Database 90A for storage and/or a computer program (not shown) for analysis.

Once the predetermined sets of apertures are examined in step 316, ULD 53 and LLD 54 are set back to GROSS_GAMMA_UPPER and GROSS_GAMMA_LOWER at step 318 and 320, respectively. The counter 74 is reset by the Main Program 80M at step 322 and pause for TAGS_INTERVAL. After TAGS_INTERVAL, the Main Program 80M retrieves the gamma count (γCount or gamma-count) from the counter 74 for that interval and assigns it to ap_count at step 326. Then, the ap_count is divided by the TAGS_INTERVAL to get the GCC_Rate at step 328. The GCC_Rate is then sent to the Apertures Database 90A for storage and/or a computer program (not shown) for analysis at step 330. If GCC_Rate is below the THRESHOLD at step 332, the Main Program 80M repeats the steps of 316 to 330; otherwise, the Main Program 80M returns to the step 300S.

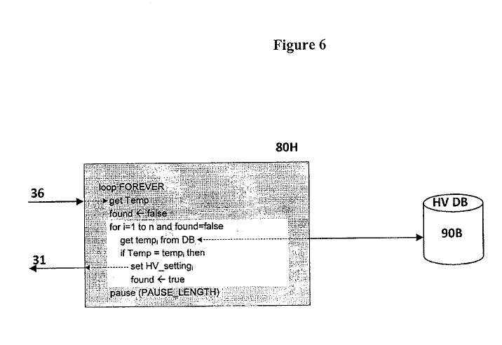

Reference is made to FIGS. 1 and 6. The High Voltage Control Program 80H provides a temperature specific HV value control, since the PMT operating high voltage (that is, the high voltage that is to be applied to the PMT for appropriate operation of the system) is partially dependent on the temperature of PMT 50.

The High Voltage Control value 22 is used to adjust the PMT's gain to match the PMT's gain determined during its calibration. Specifically, High Voltage Control value 22 adjusts the amplitude of the Charge Pulse 23 generated by the PMT 50. The manufacturer of such PMT may suggest High Voltage Control values 22 for a PMT 50 for a range of temperatures. Alternatively, High Voltage Control values 22 for a PMT 50 for a range of temperatures may be determined by calibration.

The HV Control Program 80H provides a temperature-specific HV Control Value 31, as the High Voltage value 22 is slightly dependant on operating temperature 36 of PMT 50. The HV Control Program 80H is preferably implemented in software that runs on the Detection Unit 15.

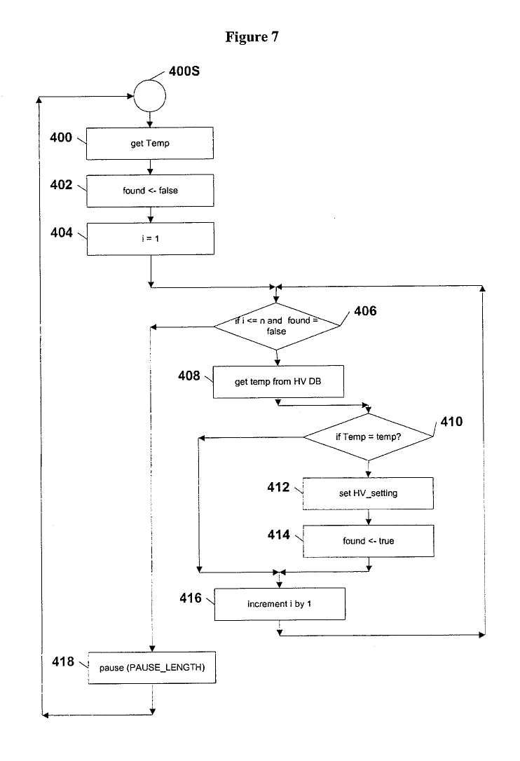

Reference is made to FIGS. 6 and 7, after various initialization (not shown), the HV Control program 80H enters to step 400S. The HV Control program 80H receives the PMT's Temperature (Temp) via 36 at the step 400. A Boolean variable, “found”, is set to false at step 402, and a counter, “i”, is set to value 1 at step 404. If “i” is less than or equal to n and “found” is false at step 406, the HV Control program 80H retrieves temp from HV database 90B at step 408. If Temp is equal to temp (at step 410), then retrieve from the database the high voltage setting associated with that temperature (using “i”), and send HV_setting 31 at step 412, set found to true at step 414. Increment value of i by 1 and return to step 406. If the condition of 406 is false, then the HV Control program 80H processes the step of 418 by pausing for PAUSE_LENGTH. In effect, according the flow chart shown in FIG. 7, the HV Control program 80H receives the PMT's Temperature 36 at every PAUSE_LENGTH time interval (for example, 30 seconds). The HV Control program 80H then searches the HV database 90B for a record matching that temperature, and retrieves the corresponding HV_Setting value 31. The HV_Setting is then passed back to the PMT 50 as the HV Control value 22.

As shown above, the Gamma Ray Detector with Targeted Automated Gamma Spectroscopy 1 functions as a dynamically adjustable Single Channel Analyzer (SCA) consisting of two electronic discriminator circuits, a Lower Level Discriminator (LLD) 54 and Upper Level Discriminator (ULD) 53 and a logic device 55.

The LLD 54 provides a means for determining if the energy of a gamma ray detected in the scintillator 40 exceeds the programmable energy threshold for that discriminator.

The ULD 53 provides a means for determining if the energy of a gamma ray detected in the scintillator 40 does not exceed the programmable energy threshold for that discriminator.

The LLD 54, ULD 53 and the logic device 55 output logic pulses for gamma rays. Using the outputs of the LLD 54 and ULD 53, the photomultiplier base with single channel analyzer 60 provides a means for combining the output logic pulses of the two discriminator circuits 53 and 54 so that the logic device 55 outputs a logic pulse 28 if and only if the energy of a gamma ray exceeds the programmable energy of the LLD 54 and does not exceed the programmable energy level of the ULD 53.

In the Gamma Ray Detector with Targeted Automated Gamma Spectroscopy 1, the threshold levels in LLD 54 and ULD 53 are set programmably by the provision of electronic circuits which are arranged so as to be under the dynamic control of a computer program (i.e. 80M). The Main Program 80M may operate so as to programmably set the LLD 54 and ULD 53 of photomultiplier base with Single Channel analyzer 60 to levels suitable for specific gamma ray energy ranges. The Main Program 80M may operate in real time (for example, the 100 millisecond time scale) so as to set the LLD 54 and ULD 53 to levels dynamically determined by the Main Program 80M or a computer operator (not shown).

The Main Program 80M controlled LLD 54 and ULD 53 together with dynamic computer program control allow for new functionalities in a gamma ray scintillation detector system or other radiation detector system so provided.

In operation of the Gamma Ray Detector with Targeted Automated Gamma Spectroscopy system 1, various functionalities are provided through the dynamic computer control (i.e. by the Main Program 80M) of the LLD 54 and ULD 53 of the photomultiplier base with single channel analyzer 60 to obtain the relative intensity of gamma rays in various certain programmably set energy intervals of the gamma ray spectrum incident upon the scintillator 40 or other radiation detection medium. This relative intensity of gamma rays is represented by the relative number of gamma rays counted in each of a series of settings of the gamma ray energy window as determined by LLD 54 and ULD 53.

These data can be transmitted from the detection unit 15 to a computing system or a data storage device (i.e. a locally or remotely located computer or computing server) (not shown) for further analysis. This analysis is conducted by a computer program which executes a comparison of the relative intensity of gamma rays from the various programmably set energy intervals of the gamma ray spectrum.

The result of this analysis is a determination of the presence of a specific radioactive gamma ray emitting isotope, which is indicated by the relative intensities of gamma rays in the various programmably set energy intervals of the gamma ray spectrum as incident on the scintillator 40, or similarly as incident on other radiation detection materials. The analysis may further be fused with temporal, spatial or both temporal and spatial relationship(s) to an event's time or location.

The number of programmably set energy intervals of the gamma ray spectrum and the gamma ray energies which correspond to the LLD 54 and ULD 53 settings for these intervals is determined on the basis of the characteristic gamma ray energies of the radioactive isotopes for which it is desirable for the Gamma Ray Detector with Targeted Automated Gamma Spectroscopy system 1 to identify and categorize as benign or threatening.

This resulting information regarding the presence of various radioactive species is made available to a Graphical User Interface (GUI). This GUI presents the radiological threat analysis data in a format compatible with conventional security operations information needs.

A plurality of Gamma Ray Detectors with Targeted Automated Gamma Spectroscopy 1 may be networked to form a system of radiological sensors with targeted automated gamma spectroscopy, which would be well suited for deployment in a wide variety of public venues and critical infrastructure locations. These include, but are not limited to:

Airports (including interior public and restricted areas, tarmac, parking, roadways, etc.);

Communities (in police and other vehicles, traffic signals, bomb squad personnel and robots, VIP protection, etc.);

Facilities (including critical infrastructure, government, industry, hospitals, financial institutions, special targets, VIP facilities, etc.);

Public Transit Systems (including subways, light rail transit, buses, etc.);

Sea Ports (including any area or building associated with a port, vehicles, vessels, cranes, buoys, etc.);

Portals (including person, vehicle and container portals deployed at borders, facility entrances, ports, etc.).

Public Gatherings and Events (including sporting events, parades, political gatherings, etc.)

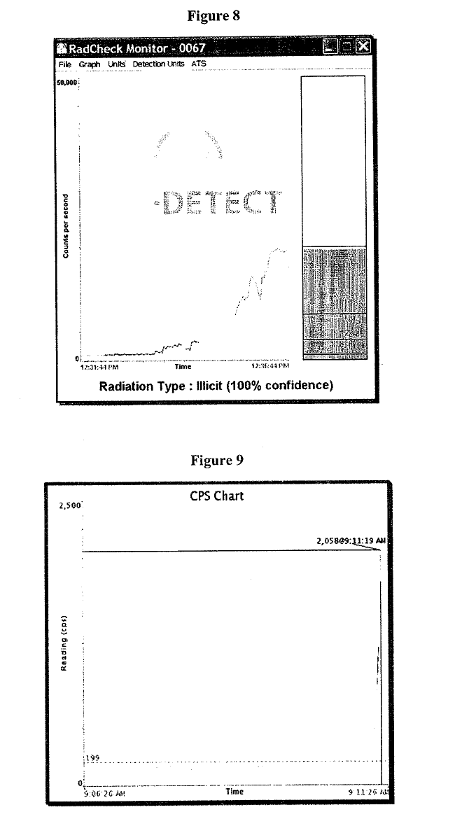

FIGS. 8, 9 and 10 are examples of test deployments of Gamma Ray Detector with Targeted Automated Gamma Spectroscopy 1. In particular, FIG. 8 shows the user interface output generated for data from a Gamma Ray Detector with Targeted Automated Gamma Spectroscopy 1 in response to a radiological source that is known (or “targeted”) by the system 1, specifically Cobalt-60 which is known by the system to be illicit. Notice the text “Radiation Type: Illicit (100% confidence)”. A user interface setting can be adjusted so that a more specific message is displayed, which in this case would be “Radiation Type: Co-60 (100% confidence)”. FIG. 8 further shows the change in gamma ray counts per second (GGC_rate) over time.

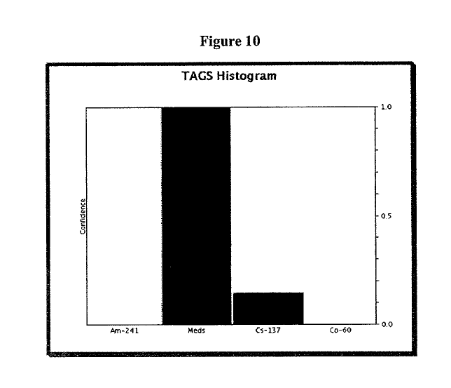

FIGS. 9 and 10 show alternate user interface outputs generated for data from a Gamma Ray Detector with Targeted Automated Gamma Spectroscopy 1 in response to a person with a radiopharmaceutical body-burden walking by the system 1. FIG. 9 shows the gross gamma count (GGC_rate) in Counts per Second (CPS) over time. FIG. 10 graphically illustrates the outcome of system analysis (not shown) by plotting a histogram of targeted automated gamma spectroscopy confidence for each pre-identified (or “targeted”) isotope or isotope group, which in this case clearly indicates a strong confidence that the radiological material detected is medical in nature.

The Gamma Ray Detector with Targeted Automated Gamma Spectroscopy system 1 can be used as a rapid and automatic spectroscopic analysis system targeted at radioactive isotopes of particular interest (both benign and threat agent). Such system has practical advantageous characteristics for deployment in a surveillance system.

These characteristics include functionalities for:

i). detection of gross gamma ray radiation levels over a wide range of gamma ray energies in order to identify and characterize normal overall radiation background levels;

ii). detection of gross gamma ray radiation levels over a wide range of gamma ray energies in order to identify variations from normal radiation levels identified by the system as above in a particular location and/or at a particular time; and

iii). automated or system operator controlled identification of gamma ray energy spectrum features which are indicators of the presence or absence of specific radiological materials and agents.

These characteristics also include the following capabilities:

i). rapid one second time scale response, including TAGS mode operation;

ii). ruggedization compatible with environmental constraints;

iii). cost effectiveness enabling deployment in large networks of sensors providing full venue coverage; and

iv). suitability for integration into conventional security operations and fusion with those and/or other security sensors.

The purpose of a gamma ray radiation surveillance system is to identify significant variations in radiation levels from historical background levels which require identification, investigation, and/or response. The magnitude of increase in radiation level which is considered significant may be defined by security operations decision makers. This decision may be based on threat assessment intelligence.

Gamma radiation surveillance conducted with the Gamma Ray Detectors with Targeted Automated Gamma Spectroscopy 1 provides measurements of the total number of gamma rays of a broad range of gamma ray energies detected during a specified time period. This allows determination of the gross gamma ray count rate. In any given location and circumstance there is a normal or background gamma ray count rate. This background can be determined, for example through the routine operation of a surveillance system. Following upon this determination of expected or background gamma ray radiation levels, it is then possible to identify subsequent radiation measurements as being statistically indistinguishable from background radiation levels or statistically significantly greater than background radiation levels. This identification is commonly conducted by the establishment of thresholds or predefined radiation measurement levels which when exceeded indicate the likelihood of anomalous radiation levels. Alternately this identification may be conducted by various statistical tests applied to the radiation measurement data in real time.

Additionally there are circumstances which lead to increases in radiation levels at a particular location or point in time which may be significantly greater than background levels. These circumstances include the legitimate presence, temporary or longer term, of medical patients with body burdens of radiopharmaceuticals, the shipment of radioactive materials in compliance with regulatory requirements, Naturally Occurring Radioactive Materials, and the legitimate use of industrial radioactive materials.

It is generally recognised that information contained in knowledge of the energies of the gamma rays detected in a surveillance system, or equivalently, knowledge of the gamma ray spectrum or spectral information, is of assistance in characterizing both background radiation levels and in characterizing higher than background radiation levels. This characterization is used in the Gamma Ray Detector with Targeted Automated Gamma Spectroscopy system 1 to distinguish those radiation measurements indicating a likelihood of the occurrence of a radiological threat and which consequently require identification, investigation and response from those radiation measurements which indicate the likelihood of the presence of benign or normal radioactive materials.

The Gamma Ray Detector with Targeted Automated Gamma Spectroscopy system 1 provides the capability of a gamma ray radiation surveillance system to both make a measurement of the gross gamma ray count rate and also to collect and analyse spectra data (and/or spectral data/information) and thereby make a determination of the presence of radiological threat agents and of benign sources of radiation in the venue under surveillance.

Various modifications may be made without departing from the spirit of the present invention. For example, the sensor technology in one embodiment of the present invention may be a cost-effective rugged plastic scintillation gamma ray detector that is specially adapted to counter terrorism applications with temperature, acceleration, vibration and electromagnetic tolerance. By utilizing various other specialized scintillation material options, both high and low energy spectral capabilities are available. Scintillation detector technology provides for the cost effective screening of common radiopharmaceuticals and the identification of illicit radiological agents.

Further by using other radiation detection media and detectors other than scintillation media coupled with a Photo Multiplier Tube and supporting electronics, other embodiments of the Gamma Ray Detector with Targeted Automated Gamma Spectroscopy system 1 may be implemented to take advantage in various applications of the functionalities of the Gamma Ray Detector with Targeted Automated Gamma Spectroscopy system 1 described herein.

While each sensor is similar, they are not identical. As such, each sensor must be calibrated to ensure that specific situations result in similar responses. The main calibration factor for scintillators is the High Voltage applied to the photomultiplier tube which is provided by the sensor manufacturer. Additionally, a targeted automated gamma spectroscopy specific calibration is performed to determine the TAGS Multiplier.

In yet another example, some modifications to the present invention may be made by having a plurality of single channel analyzers 56 or the plurality of single channel analyzers 56 being in a stacked configuration. Yet another modification may be made to the present invention by having one or more ULDs 53, one or more LLDs 54, one or more logic devices 55, and one or more counters 74, or any suitable combination thereof.

In yet another example, yet another modification may be made to the present application by connecting a single channel analyzer 56 to a plurality of counters 74 via one or more logic devices 55, or by connecting a plurality of single channel analyzers 56 to one or more counters 74 via one or more logic devices 55.

1. An analog signal measurement system comprising:
i. one or more dynamically programmable lower level discriminators configured to generate output data for an analog signal greater than a programmable level,
ii. one or more dynamically programmable upper level discriminators configured to generate output data for the analog signal less than a programmable level,
iii. one or more logic devices configured to generate output data for programmable combinations of the output data from the one or more lower level discriminators and the one or more upper level discriminators,
iv. one or more counters that programmatically count the output data of the one or more logic devices, and
v. a computing device that analyzes the counts and programmatically controls the one or more upper level discriminators and the one or more lower level discriminators with a series of one or more programmable levels,
wherein the computing device analyzes the counts and programmatically controls the one or more dynamically programmable lower level discriminators and the one or more dynamically programmable upper level discriminators with a temporally, or spatially or both temporally and spatially determined series of programmable levels.

2. (canceled)

3. (canceled)

4. (canceled)

5. The analog signal measurement system of claim 1, wherein the one or more counters programmatically count the output data of the one or more logic devices during a programmable period of time, or at a programmable time and for a programmable duration of time.

6. (canceled)

7. The analog signal measurement system of claim 1, wherein the computing device initiates the one or more counters for the counting of the output data of the one or more logic devices in a temporal, or spatial relationship to an event's time or location or in a combination thereof.

8. The analog signal measurement system of claim 1, further comprising a data storage device wherein the computing device stores the counts counted by the counter in the storage device.

9. (canceled)

10. (canceled)

11. The analog signal measurement system of claim 8, wherein the computing device analyzes the counts or stored counts.

12. (canceled)

13. The analog signal measurement system of claim 1 further comprising
a gamma ray sensing detector that converts a gamma ray into an analog signal, being communicated to the upper level discriminators and lower level discriminators.

14. (canceled)

15. The analog signal measurement system of claim 13, further comprising a computing system that analyzes the counts to determine spectral information in respect to gamma rays sensed by the gamma ray sensing detector.

16. The analog signal measurement system of claim 15, wherein the computing system analyzes the counts to determine possible threats arising from the sensed gamma rays.

17. The analog signal measurement system of claim 16, wherein the computing system numerically represents the possible threats.

18. The analog signal measurement system of claim 16, wherein the computing system graphically represents the possible threats.

19. The analog signal measurement system of claim 16, wherein the computing system fuses the possible threats with conventional or other security sensor information and data for analysis or representation.

20. A gamma detector with the capability to conduct targeted automated gamma spectroscopy comprising:
a. a gamma ray sensing detector that converts a gamma ray into an analog signal;
d. one or more single channel analyzer units that are in communication with the gamma ray sensing detector, each of the single channel analyzer units comprising a programmable upper level discriminator and a programmable lower level discriminator that define a programmable gamma ray energy window, wherein the each of the one or more single channel analyzer units receives the analog signal from the amplifier and generates digital signal pulses upon determining that the analog signal from the amplifier is within the programmable energy window;
e. one or more resettable counters that are in communication with the one or more single channel analyzer units, wherein the resettable counters receive and count the digital signal pulses from the one or more single channel analyzer units for gamma ray counts; and
f. a computing device that programmatically controls the programmable gain of the photomultiplier tube, programmatically controls the upper level discriminator and the lower level discriminator of the each of the one or more single channel analyzer units, and calculates gamma count rates based on the gamma ray counts retrieved from the one or more resettable counters.

21. (canceled)

22. The gamma detector as recited in claim 20, wherein the upper level discriminator and the lower level discriminator of the each of the one or more single channel analyzer units are dynamically programmable.

23. The gamma detector as recited in claim 20, wherein the upper level discriminator and the lower level discriminator of the one or more single channel analyzer units are dynamically programmable in real time.

24. The gamma detector as recited in claim 20, wherein the computing device further comprises a communication interface for communicating with a computing system.

25. (canceled)

26. (canceled)

27. A single channel analyzer comprising:
i. a dynamically programmable lower level discriminator configured to generate output data for analog signals greater than a programmable level,
ii. an dynamically programmable upper level discriminator configured to generate output data for the analog signals less than a programmable level,
iii. a logic device configured to generate output data for programmable combinations of the output data from the lower and upper level discriminators,
wherein the computing device analyzes the counts and programmatically controls the lower level discriminator and the upper level discriminator with a temporally, or spatially, or both temporally and spatially determined series of programmable levels.

28. (canceled)

29. (canceled)

30. (canceled)

31. The single channel analyzer of claim 27, wherein the counter programmatically counts the output data of the logic device during a programmable period of time, or at a programmable time and for a programmable duration of time.

32. (canceled)

33. The single channel analyzer of claim 27, wherein the computing device initiates the counter for the counting of the output data of the logic device in a temporal, or spatial relationship to an event's time or location, or in a combination thereof.

34. The single channel analyzer of claim 27, further comprising a data storage device, wherein the computing device stores the counts counted by the counter in the data storage device.

35. (canceled)

36. (canceled)

37. The single channel analyzer of claim 34, wherein the computing device further analyzes the counts or the stored counts.

38. (canceled)

39. A analog signal measuring system comprising a plurality of the single channel analyzers as recited in claim 27.

40. The single channel analyzer of claim 27 further comprising
a gamma ray sensing detector for converting gamma ray into an analog signal being communicated to the upper level discriminators and lower level discriminator.

41. (canceled)

42. (canceled)

43. The single channel analyzer of claim 40 further comprising a computing system that analyzes the counts to determine spectral information in respect to gamma rays sensed by a gamma ray sensing detector.

44. The single channel analyzer of claim 43, wherein the computing system analyzes the counts to determine possible threats arising from the sensed gamma rays.

45. The single channel analyzer of claim 44, wherein the computing system numerically represents the possible threats.

46. The single channel analyzer of claim 44, wherein the computing system graphically represents the possible threats.

47. The single channel analyzer of claim 44, wherein the computing system comprises information regarding possible threats with conventional or other security sensor information and data for analysis or representation to fuse the data with the security threat information.

48. A computer implemented system for gamma spectrum analysis, comprising computer implemented module that conducts targeted automated gamma spectroscopy analysis by executing an automatic comparison of the relative intensities of various gamma ray energies or groups of gamma ray energies from within various energy intervals of a gamma ray spectrum, and determines the presence or absence of specific targeted radioactive gamma ray emitting isotope or isotopes.

49. The computing system of claim 48, wherein the analysis comprises one of or both
a. numerical values of the relative intensities of gamma rays in the various energy intervals of the gamma ray spectrum; and
b. graphical representations of the numerical values of the relative intensities of gamma rays in the various energy intervals of the gamma ray spectrum.
